(19) United States
(12) Patent Application Publication
(10) Pub. No.: US 2018/0004298 A1
(43) Pub. Date: Jan. 4, 2018

(54) SYSTEM AND METHOD FOR NON-CONTACT INTERACTION WITH MOBILE DEVICES

(71) Applicant: TEXAS TECH UNIVERSITY SYSTEM, Lubbock, TX (US)

(72) Inventors: Chenhui Liu, Lubbock, TX (US); Changzhi Li, Lubbock, TX (US); Changzhan Gu, Sunnyvale, CA (US)

(73) Assignee: TEXAS TECH UNIVERSITY SYSTEM, Lubbock, TX (US)

(21) Appl. No.: 15/545,554

(22) PCT Filed: Jan. 22, 2016
(86) PCT No.: PCT/US2016/014592

§ 371 Date: Jul. 21, 2017

Related U.S. Application Data
(60) Provisional application No. 62/106,318, filed on Jan. 22, 2015.

(51) Int. Cl. G06F 3/01; H02J 50/12; H02J 7/02; H03K 17/95

(52) U.S. Cl. CPC G06F 3/017; H03K 17/9542; H02J 50/12; H02J 7/025

(57) ABSTRACT

Disclosed is a system and method for controlling handheld devices without contact by interacting with their wireless charging coils or other inductive coil antennae. The present disclosure utilizes the interaction between human body and the coil wherein the coil is used to send alternating magnetic field to interact with a control signal, such as a hand, instead of simply using the coil in the smart phone as a power receiver. The hand movement in front of the wireless charging coil changes the coil's conductivity distribution, which creates effective coil impedance also known as reflected impedance.

### CROSS-REFERENCE TO RELATED APPLICATIONS

This application is a national phase filing of PCT/US2016/014592, filed on Jan. 22, 2016, entitled “System And Method For Non-Contact Interaction With Mobile Devices” which claims priority to U.S. Provisional Patent Application Ser. No. 62/106,318, filed on Jan. 22, 2015, entitled “System and Method for Non-Contact Interaction with Mobile Devices” of which all are commonly assigned to the Assignee of the present invention and is hereby incorporated herein by reference in their entirety for all purposes.

This application includes material that is subject to copyright protection. The copyright owner has no objection to the facsimile reproduction by anyone of the patent disclosure, as it appears in the Patent and Trademark Office files or records, but otherwise reserves all copyright rights whatsoever.

### TECHNICAL FIELD OF THE INVENTION

The present invention relates in general to the field of controlling mobile devices, and more particularly, to a system and method for interacting with mobile devices in a non-contact manner, utilizing the resonant frequency of wireless charging coils or other inductive coil antennae. The interaction system supports a wide variety of scenarios involving a user's manipulation of mobile devices to control the functionality of the mobile device without the need to make physical contact with the mobile device.

### STATEMENT OF FEDERALLY FUNDED RESEARCH

None.

### BACKGROUND OF THE INVENTION

Generally, mobile devices, such as smart phones, have gradually changed from button pressing to screen touching and touch screen technology. Recently, the trend of wireless applications, including wireless charging, is developing as a competitive feature for such devices. Since mobile devices have expanded from traditional communication functions to various complex applications for things such as business, healthcare, gaming, and utility control, there remains a significant need to improve upon how mobile device users can interact with their phones.

### SUMMARY OF THE INVENTION

The present disclosure addresses failings in the art by providing a system and method for controlling a handheld or mobile device without requiring the mobile control element, such as a user's hand, finger or stylus, to make contact with the mobile device. In one embodiment, there is provided a control circuit that allows a mobile control element to interact with one or more electromagnetic fields generated by one more inductive coils disposed upon, near or within a mobile device. The one or more inductive coils may be included within one or more oscillator circuits that are disposed to form a uniform array of X by X or X by Y oscillator circuits, or dispersed in a non-uniform pattern as required to interact with the mobile device in an efficient and effective manner. Another embodiment of the present invention provides a non-contact method and system to interact with a mobile device to control the functionality of the mobile device utilizing wireless charging coils that perform the additional function of wireless power transfer (WPT). Another embodiment provides a non-contact method and system to interact with and control the functionality of the mobile device utilizing an inductive antenna coil that is configured to also support near field communications (NFC) for the mobile device. Generally, the basic premise of wireless charging or NFC is that power is wirelessly transferred based on the electromagnetic coupling between planar coils. Two kinds of devices are used—the base station and mobile device, which provides and consumes inductive power, respectively. The base station is a power transmitter that consists of a transmitting coil, and the mobile device contains a power receiver hosting a receiving coil. One embodiment of the present invention utilizes the interaction between the human body and the coil wherein the coil is used to send an alternating electromagnetic field to interact with human hand instead of simply using the coil in the smart phone as a power receiver. The hand movement in front of the wireless charging coil changes the coil's conductivity distribution, which creates effective coil impedance also known as reflected impedance.

In order to send an alternating magnetic field to interact with human hand, an oscillator circuit is utilized that incorporates a wireless power transfer coil as part of the resonant circuit. Indeed, the present disclosure provides that the impedance change results in a drift in the resonant frequency, which can be measured using a frequency counter connected to the output of the oscillator. Thus the WPT/NFC coil can recognize different mobile controller element movements, for example hand movements, that enable a user to interact with a mobile device, such as a smart phone, tablet, mp3 player, etc. without physically contacting the mobile device with the user's hand, finger or other mobile controller element used to operate, select, or control the functionality of the mobile device, as discussed in more detail below.

In another embodiment of the present invention, one or more oscillator circuits that include one or more inductive coils are included within oscillator sensor circuitry in a uniform o non-uniform array of X by X or X by Y oscillator circuits. The oscillator circuit array may be disposed upon a substrate of any suitable material. The oscillator sensor circuitry may also be positioned underneath, on top of, or adjacent to a mobile device display screen such that a user may interact with the mobile device with a mobile control element (e.g., a user's hand, finger, or stylus, etc.) by selecting display elements displayed on the mobile device display without making physical contact with the mobile device display with the mobile control element. In another embodiment, a controller analyzes the fluctuations in the resonant frequency of the oscillator circuits included in the oscillator sensor circuitry to compute the position(s) of the mobile control element relative to the display screen, or other area within the mobile device that is configured to enable mobile device functionality, processes the data sent by the oscillator circuit to determine the (1) resonant frequency of the relevant oscillator circuits, (2) the fluctuations in resonant frequency of the relevant oscillator circuits, (3) the one or more directions that the fluctuations have travelled across one or more oscillator circuits, and (4) the duration of the fluctuations or the duration that one or more oscillator circuits have been impacted due to resonant frequency fluctuations. The controller may use one or more of the aforementioned (1)-(4) determinations to generate control signals that may be transmitted to a mobile device and used by a mobile device processor to control the one or more functions performed by the mobile device. In another embodiment, one or more of the oscillator circuits included in the oscillator sensor circuit may be utilized to perform other functionality performed by the mobile device such as, for example, wireless power transmission (WPT) to wirelessly charge the mobile device, or support near field communications (NFC).

In another embodiment of the present invention, an controller is configured to receive one or more first signals from one or more oscillator circuits, process the first signal(s) to generate one more second signals that are used to control the functionality of a mobile device, and transmit the second control signal(s) to the mobile device wherein the processor may use information included within the second control signal(s) to operate the mobile device including perform certain functionality supported by the mobile device.

### BRIEF DESCRIPTION OF THE DRAWINGS

The foregoing and other objects, features, and advantages of the disclosure will be apparent from the following description of embodiments as illustrated in the accompanying drawings, in which reference characters refer to the same parts throughout the various views. The drawings are not necessarily to scale, emphasis instead being placed upon illustrating principles of the disclosure:

FIG. 1 depicts a circuit model of inductive non-contact interaction.

FIG. 2 depicts an oscillator circuit with inductive coil.

FIG. 3 depicts one embodiment of the present invention including an oscillator circuit utilized in the a control circuit to control a mobile device wherein the oscillator circuit utilizes an off-the-shelf wireless power transfer coil as the inductive coil to enable non-contact interaction with a mobile device, in this instance a mobile phone.

FIG. 4 shows a short-time FFT of resonant waveform when control element movement is performed in front of the inductive coil.

FIG. 5 depicts a zoom-in view around fundamental resonant frequency of the coil. (a), (b) and (c) show how resonant frequency changes when different control element movement (waved once, twice, and three times, respectively) is performed in front of the coil in 0.8 second.

FIG. 6 depicts one embodiment of a mobile device control system.

FIG. 7 depicts a block diagram of one embodiment of a controller.

FIG. 8 depicts one embodiment of an oscillator sensor circuitry with an example of a controller.

FIG. 9 depicts an example of a method for transmitting signals between one or more oscillator circuits and a controller.

### DETAILED DESCRIPTION OF THE DISCLOSURE

While the making and using of various embodiments of the present disclosure are discussed in detail below, it should be appreciated that the present disclosure provides many applicable inventive concepts that can be embodied in a wide variety of specific contexts. The specific embodiments discussed herein are merely illustrative of specific ways to make and use the disclosure and do not delimit the scope of the disclosure.

All publications and patent applications mentioned in the specification are indicative of the level of skill of those skilled in the art to which this disclosure pertains. All publications and patent applications are herein incorporated by reference to the same extent as if each individual publication or patent application was specifically and individually indicated to be incorporated by reference.

The present disclosure will now be described more fully hereinafter with reference to the accompanying drawings, which form a part hereof, and which show, by way of illustration, specific example embodiments. Subject matter may, however, be embodied in a variety of different forms and, therefore, covered or claimed subject matter is intended to be construed as not being limited to any example embodiments set forth herein; example embodiments are provided merely to be illustrative. Likewise, a reasonably broad scope for claimed or covered subject matter is intended. Among other things, for example, subject matter may be embodied as methods, devices, components, or systems. Accordingly, embodiments may, for example, take the form of hardware, software, firmware or any combination thereof (other than software per se). The following detailed description is, therefore, not intended to be taken in a limiting sense.

Throughout the specification and claims, terms may have nuanced meanings suggested or implied in context beyond an explicitly stated meaning. Likewise, the phrase “in one embodiment” as used herein does not necessarily refer to the same embodiment and the phrase “in another embodiment” as used herein does not necessarily refer to a different embodiment. It is intended, for example, that claimed subject matter include combinations of example embodiments in whole or in part.

In general, terminology may be understood at least in part from usage in context. For example, terms, such as “and”, “or”, or “and/or,” as used herein may include a variety of meanings that may depend at least in part upon the context in which such terms are used. Typically, “or” if used to associate a list, such as A, B or C, is intended to mean A, B, and C, here used in the inclusive sense, as well as A, B or C, here used in the exclusive sense. In addition, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

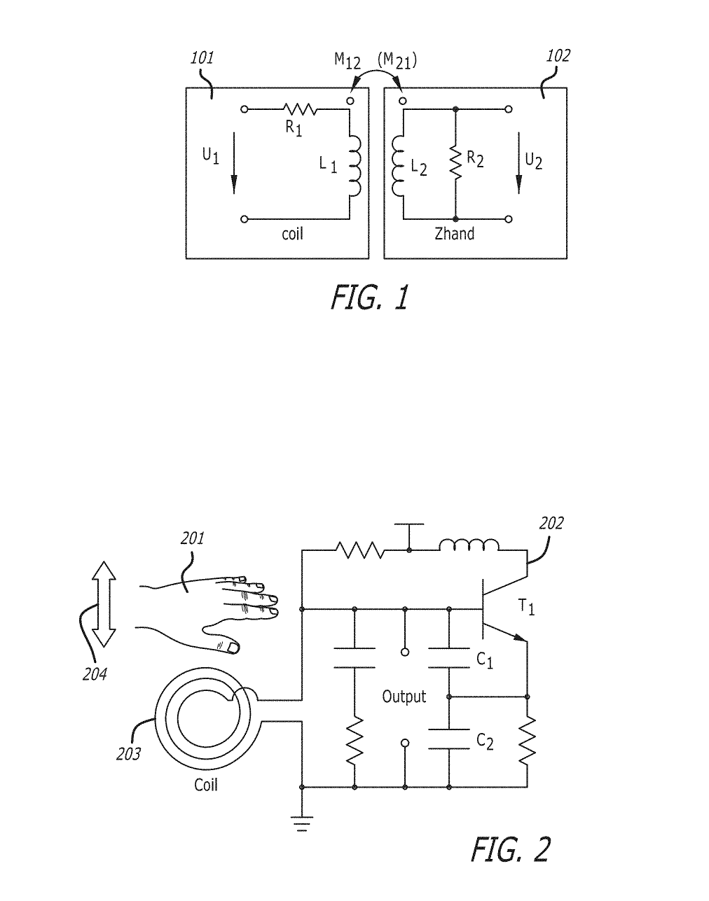

The present disclosure is described below with reference to block diagrams, formulas, and operational illustrations of methods and devices. It is understood that each block of the block diagrams or operational illustrations, and combinations of blocks in the block diagrams or operational illustrations, can be implemented by means of analog or digital hardware and computer program instructions. The present disclosure provides systems and methods for operating a mobile device, such as a smart phone, without physically touching the device. For example, hand movement in front of an inductive coil interrupts the electromagnetic near-field introduced by the coil, which results in the impedance change of the coil. This enables us for non-contact interaction with the coil by impedance measurements, which can be modeled with a transformer model, as shown in FIG. 1.

The non-contact interaction can be described with using transformer equations. The coil is modeled as inductor L₁ with resistor R₁ in series considering the resistance of the coil itself, while the human hand is modeled as L₂ and R₂ in parallel. When the human hand is brought into electromagnetic field generated by the inductance coil, the coil and the hand are electromagnetically coupled via the mutual inductance M₁₂=M₂₁. This interrelationship can be described by two equations in the frequency domain:

U₁=R₁I₁+jwL₁I₁−jwM₁₂I₂ (1)

U₂=jwL₂I₂−jwM₁₂I₁ (2)

In (2) U₂ is zero considering that a control element, such as a the hand, has high resistance. Solving (2) for I₂ and inserting the result into (1) gives the input impedance of the first mesh, which is the reflected impedance of the inductive coil Z_{ind,r} due to electromagnetic coupling with the hand:

Z_{ind,}=R₁+jwL₁+w₂M²₁₂/jwL₂ (3)

Separating equation (3) into the real and imaginary parts provides information on the effective resistance and reactance of the reflected coil impedance, which will directly affect the resonant frequency of the oscillator circuit, which consists of the inductive coil and a capacitor. One embodiment of an oscillator circuit whose frequency is determined by the coil impedance Z_{ind} is shown in FIG. 2. A control element, in this case a hand, is moving back and forth in front of the inductive coil to demonstrate the non-contact interaction between the control element and the example of the oscillator circuit. The resonant frequency is measured at the base of the transistor T₁. The frequency of the oscillator f_{osc} is given by:

$${f}_{osc} = \frac{1}{2 π} \sqrt{\frac{1}{{L}_{ind , 0} {C}_{osc}} - {( \frac{{R}_{ind}}{2 {L}_{ind , 0}} )}^{2}} \qquad ( 4 )$$

where L_{ind,0} is the inductance and R_{ind,0} is the resistance of the empty coil. The frequencies of the coil fosc with and without any object in front of the coil acting as a damping resistance can be calculated with (4) by R_{ind}=R_{ind,0} and R_{ind}=_{Rind,0}+ΔR_{ind}, respectively. As discussed, changes in conductivity distribution in front of the inductive coil due to control element movement will affect the impedance of the coil and will eventually change the resonant frequency of the oscillator circuit.

One embodiment of an oscillator circuit utilized in the control circuit and mobile device control system is depicted in FIG. 2. As shown in FIG. 2, the oscillator circuit includes an inductive coil 203 that generates an electromagnetic field, and an LC oscillator that consists of a gain device in the form of a transistor. As one may see, the output of the gain device is connected to the input to create a feedback loop. A tuned parallel LC circuit which functions as a bandpass filter to set the frequency of oscillation is also advantageous to this embodiment. A variable inductance or variable capacitor in the form of a third capacitor may also be utilized (in parallel to the inductor). The gain device may be a bipolar junction transistor, field effect transistor, operational amplifier, or vacuum tube.

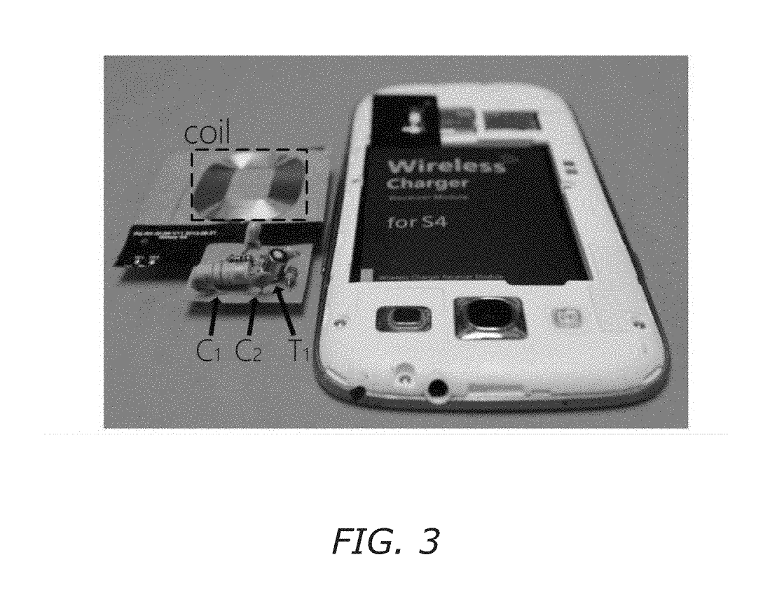

FIG. 3 illustrates one embodiment of an mobile control circuit and oscillator circuit wherein the wireless charging coil disassembled from an off-the shelf smart phone, SAMSUNG GALAXY S4® is also utilized as the inductive coil of the oscillator circuit. It should be noted that the oscillator circuit can be easily integrated into a CMOS chip and fully integrated into the phone or directly on the WPT/NFC coil board. Those having ordinary skill in the art will also understand that the inductive coil depicted here is for exemplary purposes and the present invention is limited to the type, model or inductive coil structure shown or used for experimental purposes. Additionally, the inductive coils utilized in other embodiments of the present invention may be used solely to enable a user to control the mobile device as opposed to having a dual purpose, such as wireless power transmission (WPT) for charging the mobile device.

Experiments were performed by setting the oscillator circuit upright on a table, with an oscilloscope connected to the oscillator output to measure the real-time circuit response while a control signal, in the form of a hand, was waving in front of the wireless charging coil. As discussed in herein, the impedance change directly affects the resonant frequency of the circuit.

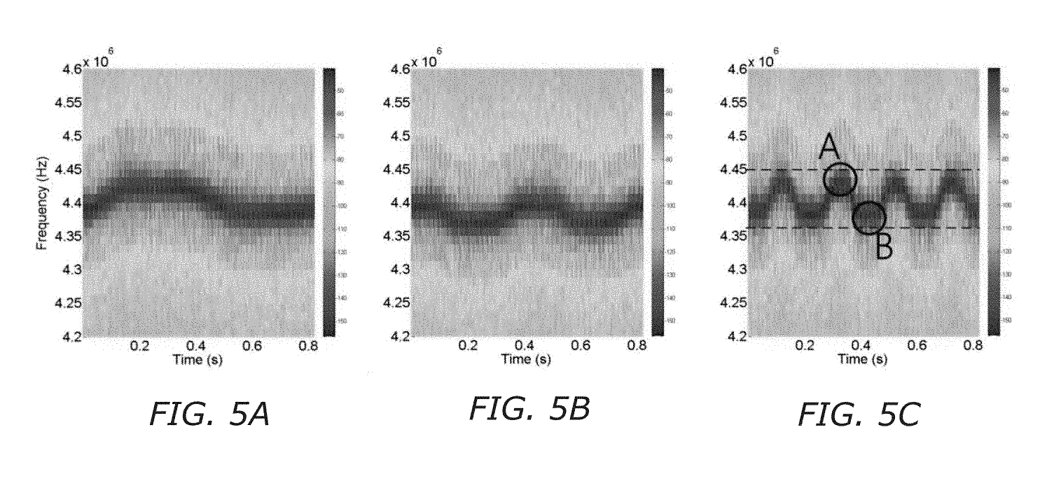

Turning to FIG. 5, considering that the interaction between human and smart phone should have a rapid response, hand movements are performed in a short time interval. In one embodiment, an oscilloscope was used to record waveform for 0.8 second. Several different control signals were performed to demonstrate that the inductive coil has different responses to various fluctuations, including, but not limited to: (1) the range of the fluctuations (amount of variance), (2) the direction of the fluctuations across multiple oscillator circuits, and (3) the duration of the fluctuations.

In a series of experiments utilizing one embodiment of the present invention, the subject person waved her hands once, twice and three times in front of the coil without touching it. The whole waveform was recorded during this 0.8 second period using the oscilloscope with a sampling rate of 50 MHz. Then short-time FFT was applied to analyze the data recorded. These signals including the measurements of impedance, charge, voltage, current, or other suitable electrical signal information at the oscillator circuits may be utilized to control the functionality of a mobile device.

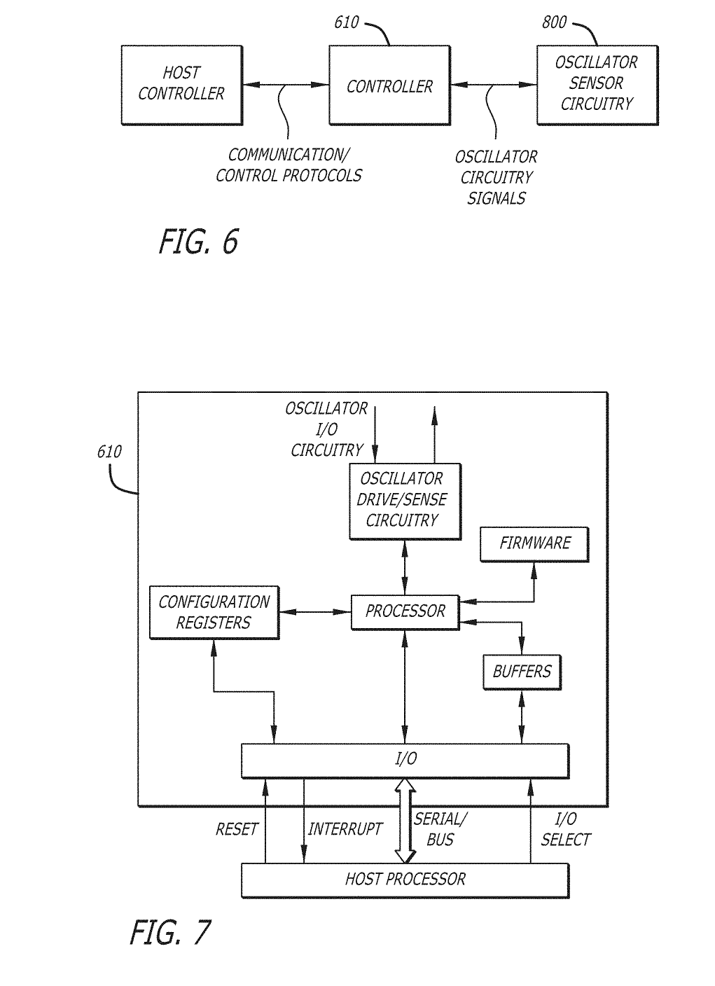

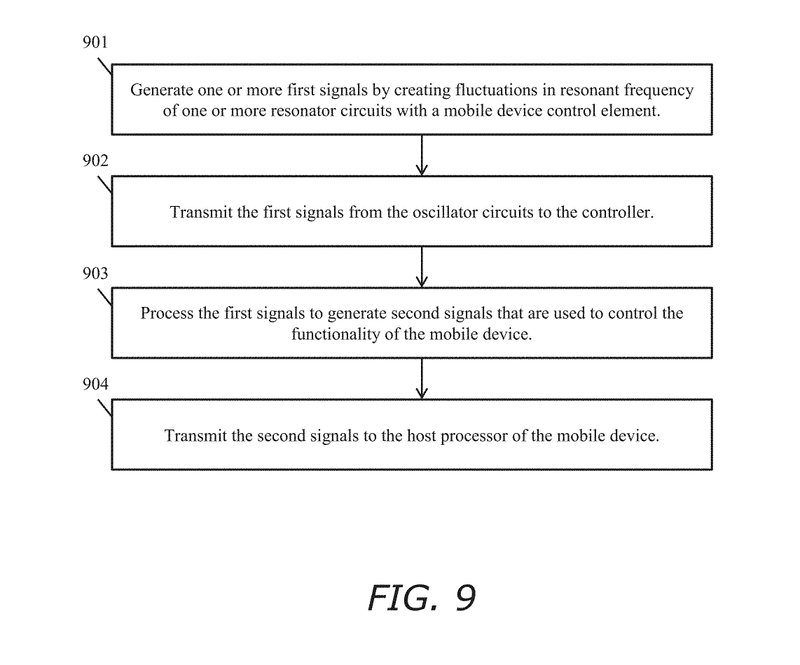

As is illustrated in FIGS. 6 and 9, a system that may utilize the mobile device control circuitry described herein may include a mobile device display screen 600, oscillator sensor circuitry 800 that forms a layer of one or more oscillator circuits that are disposed either underneath or on top of the mobile device display screen, a controller 610 that may include a CPU, an application specific integrated circuit (ASIC) or a micro-processor and that measures fluctuations in the resonant frequency of inductive coils included in the oscillator circuits disposed within the oscillator sensor circuitry 800. These fluctuations are due to the contactless interaction between a mobile device control element used to control the functionality of a mobile device and the electromagnetic fields generated by the inductive coils. The aforementioned fluctuations that are measured by the controller 610 to control the functionality of the mobile device occur without requiring the mobile device control element to come into contact with the mobile device or the oscillatory sensor device 800. For example, as is seen with respect to FIG. 2, a user of a mobile device may use his hand as the mobile controlling element to create the fluctuations in the resonant frequency of the one or more oscillator circuits and control the functionality of the mobile device. The mobile controlling element may be any suitable device that may be utilized by a user to interact with the electromagnetic fields generated by the one or more oscillator circuits disposed within the oscillatory sensor device 800 without requiring the mobile device control element to make contact with the mobile device and/or the oscillatory sensor device 800, such as a hand, finger, stylus, etc.

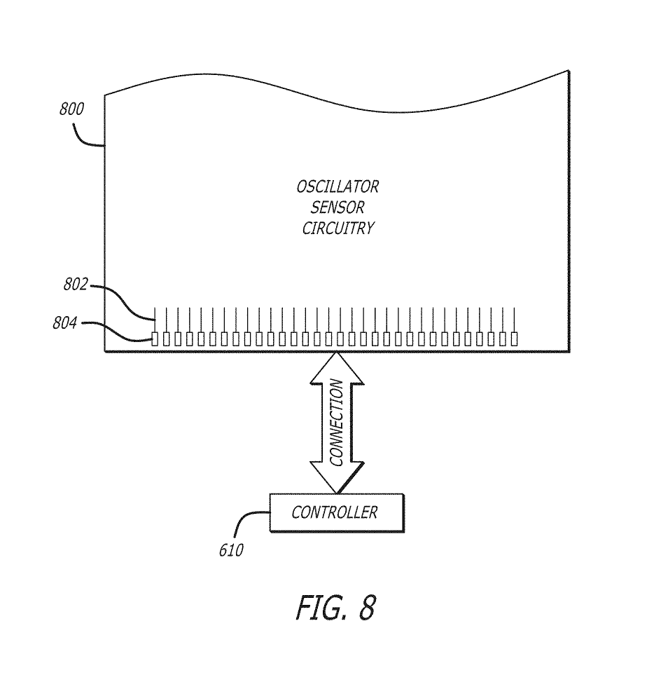

FIG. 8 shows an example of an oscillator sensor circuit device 800 with an associated controller 610. Oscillatory sensor device 800 and controller 610 may detect the presence and location of a control element within the sensor area of an oscillatory sensor 804, and determine the time in which the resonant frequency is impacted at one or across different oscillation nodes. Although FIG. 8 depicts multiple oscillatory sensor circuits with their associated sensing lines 802 formed within an array configuration, there exist numerous configurations in which the oscillatory sensors 804 may be disposed to enable a control element to interact with and control a mobile device. For example, in one embodiment of the present invention the oscillatory sensor device 800 may include one oscillatory circuit which includes a single inductive coil. In another embodiment of the present invention, the oscillatory sensor device 800 may include an array of oscillatory circuits 804 disposed on one or more substrates. In another embodiment of the present invention, the same inductive coil(s) that may be used to wirelessly charge the mobile device through wireless power transmission (WPT) processes may be included in the oscillatory sensor circuitry 800 as an inductive coil and used to control the mobile device such that the same inductive coil will be used for a multiple functions (e.g., power transmission and functionality control).

Where the oscillatory sensor device 800 utilizes multiple oscillatory circuits 804, sensor device 800 may include an array of inductive coils that may each form a resonant frequency node. When a control element is used to interact with the mobile device, a change in the resonant frequency of the inductive coil may occur at the resonant frequency node and the controller 610 may determine the position of the control element, the strength of the resonant frequency, the change in the resonant frequency and the duration of the resonant frequency at each of the frequency nodes. Additionally, one or more sense lines 802 may run horizontally across the oscillatory sensor device 800 to intersect the vertical sense lines 802 shown in FIG. 8. In this embodiment, the resonant frequency information transmitted by the horizontal sensing lines will also be measured by the controller 610. Alternatively, the CPU or micro-processor utilized by and disposed within the mobile device, for example the host processor illustrated in the block diagram of FIG. 7, may determine any or all of the information that the controller processor determines.

In an alternative embodiment, the vertical oscillator sensing lines 802 and the horizontal oscillator sensing lines 802 (not shown) may come near each other but not make electrical contact with one another. In another embodiment of the present invention, a pulsed or alternating voltage may be applied to each of the oscillator circuits. As in the other embodiments of the present invention, a change in the resonant frequency of each of the resonant inductive coils due to the interaction of a control element with the oscillatory sensor device 800 may be measured along with other parameters by the controller to control one or more functionalities of the mobile device. By measuring changes in the resonant frequency throughout the array of one or more oscillator circuits, controller 610 may determine the position of the mobile control element, the duration of interaction between the one or more oscillator circuits and the one or more control elements and, in combination with host processor 700 shown in FIG. 7, enable a user to interact with and control one or more functionalities of the mobile device.

In particular embodiments of the present invention, one or more oscillator circuits may together form a resonant sense line 802 running horizontally or vertically or in any suitable configuration. Similarly, one resonant sense line 802 running horizontally and one resonant sense line 802 running vertically may intersect or come nearest each other to form a resonant inductive node. The change in resonant frequency across one or more oscillator circuits 804 as a result of interaction with a control element may be measured at the inductive coils that are included in the oscillator circuits 804, at one or more resonant frequency nodes, or any combination of the two. Moreover, this disclosure contemplates any suitable method to detect a change in the resonant frequency of an inductive coil.

After detecting a change in resonant frequency, controller 610 may then communicate information about the resonant frequency to one or more components (such one or more central processing units (CPUs)) of a device that includes oscillator sensor circuit device 800 and controller 610, which may respond to the resonant frequency input by initiating a function of the mobile device or a software application running on the mobile device, or help in initiating or performing some function of the mobile device. Although this disclosure describes a particular controller having particular functionality with respect to a mobile device and a particular oscillator circuit 804, this disclosure contemplates any suitable controller that has the ability to determine the types of measurements necessary to initiate a function of a mobile device or a software application running on the mobile device, or help to initiate or perform one or more functions of the mobile device.

Controller 610 may be one or more integrated circuits (ICs), general-purpose microprocessors, microcontrollers, programmable logic devices (PLDs) or programmable logic arrays (PLAs), or application-specific ICs (ASICs). In particular embodiments, controller 610 comprises analog circuitry, digital logic, and digital non-volatile memory. In particular embodiments, controller 610 is disposed on a flexible printed circuit (FPC) bonded to the substrate of oscillatory sensor device 800. The FPC may be active or passive, where appropriate. In particular embodiments multiple controllers 610 are disposed on the FPC. In accordance with one embodiment as depicted in FIG. 7, controller 610 may include a processor unit, an oscillator I/O circuitry that includes drive and sensing circuitry, one or more software and firmware modules, and local memory. Controller 610 has the ability to sense and analyze (e.g., measure) the coordinates and fluctuations of the changes in resonant frequency and the time intervals between the changes in resonant frequency that occur within the one or more oscillator circuits 804 disposed within the oscillatory sensor device 800. A user may navigate and interact with graphical user interfaces on a mobile display screen affixed to a mobile device due to the tracking of the fluctuations in the resonant frequency of the one or more oscillator circuits 804. To control certain functionality of the mobile device, it may be necessary to detect multiple resonant frequency fluctuations that occurred within the one or more oscillator circuits disposed within the oscillatory sensor device 800 due to the interaction between a mobile device control element and the electromagnetic field generated by the one or more oscillator circuits. The size and sensitivity of the grid of oscillator circuits include within the oscillatory sensor device 800 is driven by the desired resolution of the above mentioned fluctuations.

The oscillator I/O circuitry may supply drive signals to the oscillator sensors of oscillatory sensor device 800. Drive signals may take any suitable waveform or be of any suitable frequency, number, or duration, in particular embodiments. Drive signals may be periodic signals driven at a suitable frequency. The oscillator I/O circuitry may sense resonant frequency, impedance, charge, voltage, current, or another other suitable electrical signal information at the oscillator circuits 804 and/or the resonant frequency nodes of oscillatory sensor device 800 and provide measurement signals to the processor unit representing the change in resonant frequency at the inductive coils. Controller 610 can simultaneously resolve and track multiple resonant frequency fluctuations that occur due to the mobile device control element interacting with the electromagnetic field generated by the inductive coils included in the oscillator circuits. The aforementioned fluctuations that are measured by the controller 610 to control the functionality of the mobile device occur without requiring the mobile device control element to come into contact with the mobile device or the oscillatory sensor device 800. A high refresh rate allows the controller 610 to track rapid fluctuations within the resonant frequency of the one or more oscillator circuits and interactions between a mobile device control element due to movements of the same through the electromagnetic field(s) generated by the oscillator circuits and any additional movements without appreciable delay. The embedded processor filters the data, identifies the resonant frequency fluctuation coordinates and reports them to the host. The embedded firmware can be updated via patch loading. Processing may be performed on the sensed signals to determine any suitable characteristic of the signals, such as resonant frequency of the one or more signals, spectral frequencies of the one or more signals, signal amplitude, and changes in the aforementioned signal characteristics. The processor unit may also control the drive signals to the oscillator circuits disposed within the oscillatory sensor device 800 by the oscillator I/O circuitry and process measurement signals transmitted from the oscillator I/O circuitry to detect and process the presence, duration, and location of a change in the resonant frequency due to the interaction of a mobile control element with the mobile device via one or more electromagnetic-sensitive areas of oscillatory sensor device 800. The processor unit may also track changes in the position of the mobile control element or resonant input within the electromagnetic-sensitive areas of oscillatory sensor device 800 and the duration of the time intervals in which these oscillator circuits are impacted. The storage unit may store programming for execution by the processor unit, including programming for controlling the oscillator I/O circuitry to supply drive signals to the oscillator circuits disposed within the oscillatory sensor device 800, programming for processing measurement signals from the oscillator I/O circuitry, and other suitable programming to enable the controller to communicate the necessary information to the mobile device host processor to interact with and control the mobile device functionality.

The mobile device that may be controlled by the one or more embodiments of the present invention include a computer, a notebook computer, a laptop computer, a personal data assistant (PDA), a mobile telephone, a smart phone, an electronic book reader, a radio, an MP3 player, and a portable music player, or any other suitable mobile device known by those having skill in the art and have a display. The mobile device may have a display and an oscillatory sensor device 800 with a electromagnetically sensitive areas due to the one or more oscillator circuits disposed within the oscillatory sensor device 800. The mobile device display may be a liquid crystal display (LCD), a LED display, a LED-backlight LCD, plasma display, or other suitable display.

The functionality of a mobile device, for example a feature or smartphone, may be controlled using the mobile device control signals transmitted from the controller 610 to the mobile host processor. In turn, the mobile device electronics provide the functionality of mobile device, including the mobile device functionality that may be controlled due to the interaction of the mobile device control element with the oscillatory sensor device 800 disposed adjacent to the mobile device display and in another suitable location upon or within the mobile device. For example, a mobile device may include electronics and other circuitry to enable the mobile device to communicate wirelessly to or from the device to display information to a user, execute programming on the device, generate graphical or other user interfaces (UIs) for the device, manage power functions and enter into and out of different states of power consumption, take and/or transmit pictures, record audio/visual information, or any suitable combination of these and other functionalities well-known in the art. Additionally, a mobile device may be controlled by the aforementioned embodiments of the present invention to display a field to enter a URL for a mobile web site, a calculator, a numerical Roman numeral telephone display, a menu, an icon, an alarm clock, a calendar, a field to enter text information, text messages, text messaging information, a game, a document, global positioning system information, global positioning system functionality, navigation functionality, push to talk functionality, roaming information, roaming functionality, cellular network information, a website, web content, a power management setting, email information, email content, email functionality, a folder, folder content, a note, a reminder, music, digital photographs, videos, locally stored information, and software application content, or any other information known to be displayed by a mobile device by a person having ordinary skill in the art.

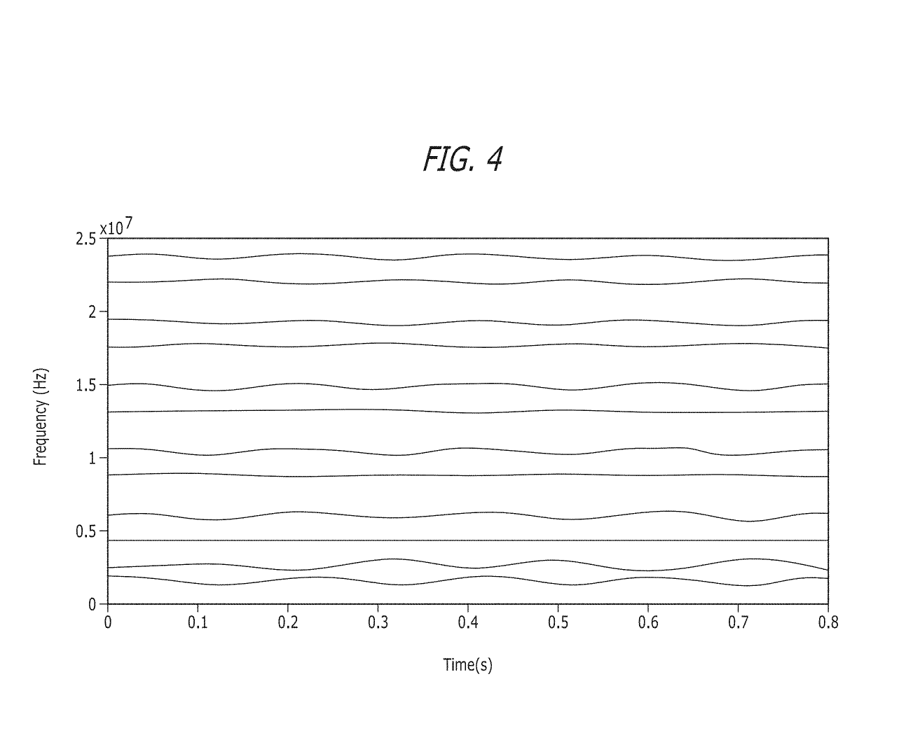

FIG. 4 shows the short-time FFT results of monitoring hand movements. From the result it is shown that the fundamental frequency is around 5 MHz, which is the resonant frequency of the oscillator built based on the wireless charging coil. There are higher order harmonics of the fundamental tone, from which we can easily observe that there are variations of the oscillation frequency due to hand movement in front of the coil. However, when a zoom-in view of the fundamental frequency is observed, the resonant frequency drift can also be easily observed. FIG. 5 shows the change of the fundamental frequency due to hand movements.

The zoom-in view of the fundamental frequency variation clearly demonstrates the effect that hand movement on the coil's resonant frequency. Taking FIG. 5 (c) as example, “A” has a resonant frequency of about 4.45 MHz while “B” is around 4.35 MHz, which means “A” is where the hand is closest to the coil and “B” is where the hand is the farthest from the coil. The resonant frequency of the inductive coil keeps changing as hand moves towards and away from the coil. These changes in resonant frequency can be further processed to interact with smart phones and mobile devices, which makes hand movement interaction with smart phones possible.

According to the exemplary embodiments, the present disclosure utilizes the above approach to utilize inductive coils of mobile devices as a wireless sensor for non-contact hand interaction based on standard smart phone WPT/NFC coils. An oscillator circuit is built using the inductive coil as part of the resonant circuit to send electromagnetic field to interact with human hand. Hand movement without touching anything will affect the impedance of the coil, which will result in variation of the oscillator resonant frequency.

In another embodiment, smaller inductive coils and respective oscillator circuits may be utilized to control the functionality of a mobile device. Indeed, any configuration of X by X or Y by Y arrays of uniformly spaced or non-uniformly spaced oscillator circuits may be utilized by the present invention. For example, if the control circuit of the present invention receives oscillator sensor circuitry signals for a swipe wherein the sensor includes a plurality of oscillator circuits formed in a 2×2, 4×4, 16×16, etc. array, this means that the resonant frequency of multiple oscillator circuits have been impacted due to the non-contact interaction between a mobile device control element and the induction coils of the oscillator circuits such that they are measurable. In this instance, measurements of electrical characteristics, such as the resonant frequency, may be taken across inductance coils electromagnetically engaged and adjacent coils to figure out the type of gesture that was performed. These measurements may include a comparison of measurements across multiple oscillator circuits to determine direction of swipe, duration of swipe, and the change in resonance frequency. Alternatively, the speed of the swipe may also be calculated if the host processor requires that information within the control signals sent by controller to control the functionality of the mobile device. One or more oscillator circuits may be disposed anywhere within or adjacent to any surface of the mobile device, not just adjacent to the display screen, to control mobile device functionality.

In other embodiments, the variation of the oscillation frequency is shown, hence making noncontact interaction between human and smart phones possible. A standard smart phone WPT/NFC coil is measured 2.8 cm×3.2 cm, which is much smaller than a mobile device. It is thus possible to embed a 2×2 coil array inside a mobile device, such as a smart phone. With this arrangement, the smart phone can detect relative distance of the hand, more gesture patterns, and the direction of hand movements in a plane parallel with the phone.

Those skilled in the art will recognize that the methods and systems of the present disclosure may be implemented in many manners and as such are not to be limited by the foregoing exemplary embodiments and examples. In other words, functional elements being performed by single or multiple components, in various combinations of hardware and software or firmware, and individual functions, may be distributed among software applications at either the client level or server level or both. In this regard, any number of the features of the different embodiments described herein may be combined into single or multiple embodiments, and alternate embodiments having fewer than, or more than, all of the features described herein are possible.

Functionality may also be, in whole or in part, distributed among multiple components, in manners now known or to become known. Thus, myriad software/hardware/firmware combinations are possible in achieving the functions, features, interfaces and preferences described herein. Moreover, the scope of the present disclosure covers conventionally known manners for carrying out the described features and functions and interfaces, as well as those variations and modifications that may be made to the hardware or software or firmware components described herein as would be understood by those skilled in the art now and hereafter.

Furthermore, the embodiments of methods presented and described as flowcharts in this disclosure are provided by way of example in order to provide a more complete understanding of the technology. The disclosed methods are not limited to the operations and logical flow presented herein. Alternative embodiments are contemplated in which the order of the various operations is altered and in which sub-operations described as being part of a larger operation are performed independently.

While various embodiments have been described for purposes of this disclosure, such embodiments should not be deemed to limit the teaching of this disclosure to those embodiments. Various changes and modifications may be made to the elements and operations described above to obtain a result that remains within the scope of the systems and processes described in this disclosure.

What is claimed is:

1. A control circuit suitable for contactless interaction with a mobile device, the circuit configured to control the functionality of a mobile device, the control circuit comprising:
a power supply,
an oscillator circuit configured to electromagnetically engage a control element, the oscillator circuit comprising:
at least one inductive coil,
a gain device,
and a parallel LC circuit,
the at least one inductive coil configured to generate a resonant frequency and to generate an electromagnetic field,
the oscillator circuit configured to enable the control element to vary the resonant frequency of the at least one inductive coil without contacting the mobile device, wherein certain functionality within the mobile device can be controlled by varying the resonant frequency of the oscillator circuit.

2. The control circuit of claim 1, wherein the gain device includes a bipolar junction transistor.

3. The control circuit of claim 1, wherein the gain device includes a field effect transistor.

4. The control circuit of claim 1, wherein the gain device includes an operational amplifier.

5. The control circuit of claim 1, wherein at least one inductive coil is additionally configured to operate as a power transfer device to receive power from a power source and provide power to the mobile device to charge the mobile device.

6. The control circuit of claim 1, wherein the parallel LC circuit is included in a feedback loop connected to the gain device such that the output of the gain device is connected to the input of the feedback loop.

7. The control circuit of claim 6, wherein the parallel LC circuit includes at least two capacitors that are disposed in parallel with the inductive coil.

8. The control circuit of claim 6, wherein the parallel LC circuit includes a bandpass filter to set the frequency of oscillation within the inductive coil.

9. The control circuit of claim 1, wherein the control circuit is configured to detect when the control element engages the oscillator circuit to control the mobile device to display at least one of the following, a field to enter a URL for a mobile web site, a calculator, a numerical Roman numeral telephone display, a menu, an icon, an alarm clock, a calendar, a field to enter text information, text messages, text messaging information, a game, a document, global positioning system information, global positioning system functionality, navigation functionality, push to talk functionality, roaming information, roaming functionality, cellular network information, a website, web content, a power management setting, email information, email content, email functionality, a folder, folder content, a note, a reminder, music, digital photographs, videos, locally stored information, and software application content.

10. The control circuit of claim 7, wherein the parallel LC circuit further includes a variable capacitor that is connected in parallel to the inductive coil and configured to tune the oscillator circuit.

11. The control circuit of claim 10, wherein the control circuit is further configured to detect a time interval wherein the control element engages the oscillator circuit.

12. The control circuit of claim 11, wherein the control circuit is further configured to use the detected time interval to control the mobile device.

13. The control circuit of claim 1, wherein the mobile device is one of a computer, a notebook computer, a laptop computer, a personal data assistant (PDA), a mobile telephone, a smart phone, an electronic book reader, a radio, an MP3 player, and a portable music player.
